(19) United States
(12) Patent Application Publication
(10) Pub. No.: US 2011/0070707 A1
(43) Pub. Date: Mar. 24, 2011

(54) METHOD OF MANUFACTURING NOR FLASH MEMORY

(75) Inventor: Yung-Chung Lee, Chu-Pei City (TW)

(73) Assignee: EON SILICON SOLUTION INC., Chu-Pei City (TW)

(21) Appl. No.: 12/562,936

(22) Filed: Sep. 18, 2009

(51) Int. Cl. H01L 21/336

(52) U.S. Cl. 438/266; 257/E21.422

(57) ABSTRACT

In a method of manufacturing a NOR flash memory, two times of tilt ion implantation process are conducted to form a tilt-implanted source region, so as to improve the distribution of the source region in a semiconductor substrate and reduce the probability of short channel effect (SCE) between the drain regions and the source region in the NOR flash memory.

### FIELD OF THE INVENTION

The present invention relates to a method of manufacturing a NOR flash memory, and more particularly to a method of manufacturing a NOR flash memory in which an improved source ion implantation process is used.

### BACKGROUND OF THE INVENTION

With the progress in semiconductor process technique, the size of the metal-oxide-semiconductor (MOS) is gradually reduced to enable largely reduced manufacturing cost and increased component integration of integrated circuits. However, the short channel effect (SCE) due to the reduced MOS size brings many problems, such as threshold voltage shift, threshold voltage roll-off, etc. Thus, it is very important to workout a semiconductor structure applicable for ultra-short channel devices.

FIG. 1 is a top view showing part of a NOR flash memory array. As shown, the NOR flash memory array includes a plurality of gate structures 102 serving as memory cells. These gate structures 102 are connected via a control gate 102d deposited thereon to form a plurality of longitudinally arranged word lines. Each of the gate structures 102 adjoins a drain region 104 and a source region 106. As can be seen from FIG. 1, the drain regions 104 between two lines of gate structures 102 are provided with a contact hole 110 each. The contact holes 110 allow the gate structures 102 to electrically connect to bit lines (not shown), which are perpendicular to the word lines. In the NOR flash memory array, there are formed a plurality of shallow trench isolation (STI) structures 112, which are perpendicular to the word lines and space two adjacent gate structures 102 in the same line from each other.

FIG. 2 is a cross sectional view taken along line B-B′ of FIG. 1 to show the structure of the conventional NOR flash memory. As shown in FIG. 2, on a semiconductor substrate 100, there is formed a gate structure 102, which includes a tunnel oxide layer 102a, a floating gate 102b, a dielectric layer 102c, a control gate 102d, and two oxide walls 202 separately located at two opposite lateral sides of the gate structure 102. A shallow-doped drain region 104a and a deep-doped drain region 104b forming an abrupt junction of a drain region 104 are formed in the semiconductor substrate 100 at one of the two opposite lateral sides of the gate structure 102. Meanwhile, a first source region 106a and a second source region 106b are formed in the semiconductor substrate 100 at the other lateral side of the gate structure 102 through conventional source ion implantation process. With the reduction in the size of the memory, the first source region 106a formed through the conventional source ion implantation process is relatively closer to the shallow-doped drain region 104a, resulting in increased probability of short channel effect between the first source region 106a and the shallow-doped drain region 104a.

FIG. 3 is a longitudinal sectional view taken along line A-A′ of FIG. 1 to show the structure of the conventional NOR flash memory, and the area shown in FIG. 3 corresponds to the framed area 130 in FIG. 1. FIG. 3 shows the performing of a conventional self-aligned source ion implantation process. In the conventional source ion implantation process, first use a mask 204 to cover portions above the shallow-doped drain region 104a and the deep-doped drain region 104b. Then, progress a first time source ion implantation process 206a at a tilt incident angle, followed by a second time source ion implantation process 208 at a vertical incident angle, and finally a third time source ion implantation process 206b at a tilt incident angle. The first source region 106a formed through the conventional source ion implantation process is very close to the shallow-doped drain region 104a, as can be seen from FIG. 2. Therefore, the short channel effect tends to occur when the device is reduced in size.

### SUMMARY OF THE INVENTION

A primary object of the present invention is to provide a method of manufacturing a NOR flash memory, in which an improved source ion implantation process is employed to improve the distribution of an implanted source region in a semiconductor substrate, so as to effectively reduce the probability of short channel effect (SCE) in a size-reduced NOR flash memory.

To achieve the above and other objects, the method of manufacturing a NOR flash memory according to the present invention includes the following steps: (1) forming a plurality of shallow trench isolation (STI) structures in a semiconductor substrate at intervals of about 50 to 150 nm; (2) forming a plurality of gate structures on the semiconductor substrate, and the gate structures being formed into line and connected to one another via a control gate; and the control gate being located on the semiconductor substrate in a direction normal to the STI structures; (3) progressing a shallow-doped drain ion implantation process to form a plurality of shallow-doped drain regions in the semiconductor substrate at one of two opposite lateral sides of the gate structures; (4) forming an oxide wall at each of the two opposite lateral sides of the gate structures; (5) progressing a deep-doped drain ion implantation process to form a plurality of deep-doped drain regions in the semiconductor substrate at one of the two lateral sides of the gate structures, so that the shallow-doped drain regions and the deep-doped drain regions are located in the semiconductor substrate at the same side of the gate structures; (5) progressing an etching process to etch away portions of the STI structures in the semiconductor substrate at the other lateral side of the gate structures without the drain regions, so as to form a plurality of openings; and (6) progressing a tilt ion implantation process to form a tilt-implanted source region in the semiconductor substrate at the other lateral side of the gate structure without the drain regions and below the openings.

According to the method of the present invention, the semiconductor substrate is a p-type semiconductor substrate.

According to the method of the present invention, the tilt ion implantation process includes a first time tilt ion implantation process and a second time tilt ion implantation process; and in both of the first and the second time tilt ion implantation process, ions are implanted into the semiconductor substrate at an incident angle of about 25 to 35 degrees.

Moreover, according to the method of the present invention, in the first and the second time tilt ion implantation process, ions are implanted with an implant energy of about 20˜60 KeV and at an implant dose of about 1×10¹⁴˜1×10¹⁵ atom/cm².

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a top view of a NOR flash memory array;

FIG. 2 is a cross sectional view taken along line B-B′ of FIG. 1;

FIG. 3 is a longitudinal sectional view taken along line A-A′ of FIG. 1; and

FIGS. 4 to 9 are longitudinal sectional views showing different steps included in a method of manufacturing a NOR flash memory according to an embodiment of the method of the present invention; and

FIG. 10 is a cross sectional view of a NOR flash memory manufactured using the method according to an embodiment of the present invention.

### DETAILED DESCRIPTION OF THE PREFERRED EMBODIMENTS

The present invention will now be described with a preferred embodiment thereof. For the purpose of easy to understand, elements that are the same in the illustrated embodiment and drawings are denoted by the same reference numerals.

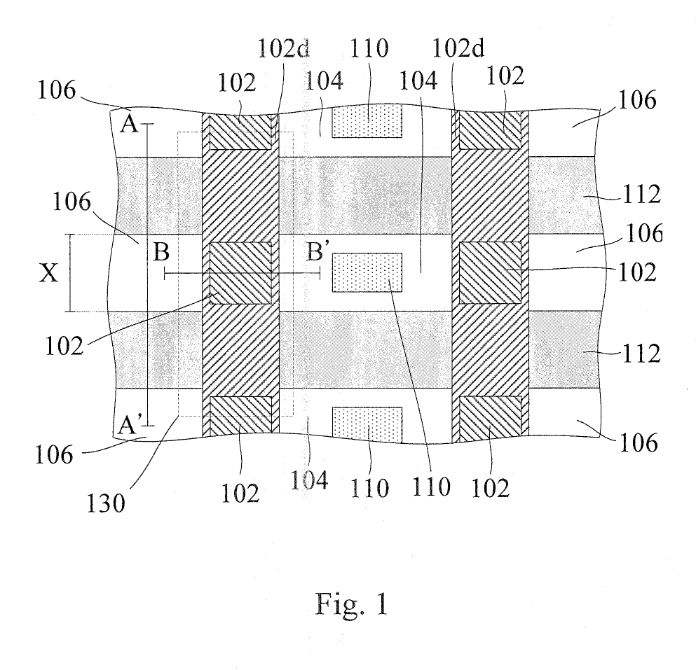

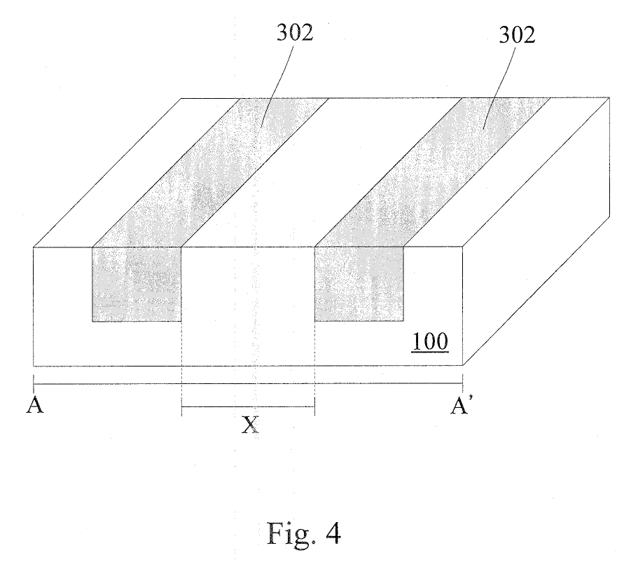

In the method of manufacturing a NOR flash memory according to the present invention, the manner of implanting ions in the source ion implantation process is improved. In the illustrated preferred embodiment of the present invention, the memory structure is an N-channel memory structure and has n-type source region and drain region. FIGS. 4 to 9 are longitudinal sectional views showing different steps included in the method of manufacturing a NOR flash memory according to an embodiment of the present invention. The area shown in FIGS. 4 to 9 corresponds to the framed area 130 in FIG. 1 and is taken along line A-A′ thereof.

Please refer to FIG. 4. In a first step of the present invention, a p-type semiconductor substrate is formed by implanting boron (B) ions into a semiconductor substrate 100 at an implant dose about 1×10¹² atom/cm². Then, a plurality of shallow trench isolation (STI) structures 302 is formed in the semiconductor substrate 100 at intervals X of about 50˜150 nm. In FIGS. 4 to 10, only two shallow trench isolation structures 302 are shown. The material for the semiconductor substrate 100 can be silicon (Si), silicon-germanium (SiGe), silicon on insulator (SOI), silicon germanium on insulator (SGOI), or germanium on insulator (GOI). In the illustrated embodiments of the present invention, the semiconductor substrate 100 is a silicon substrate.

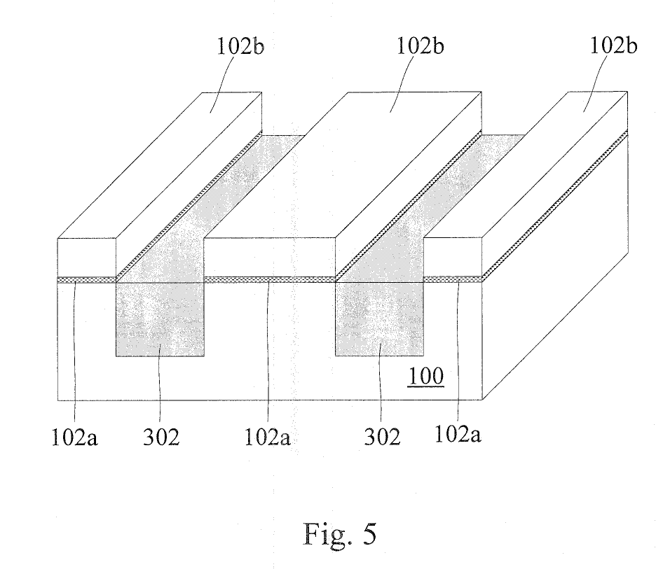

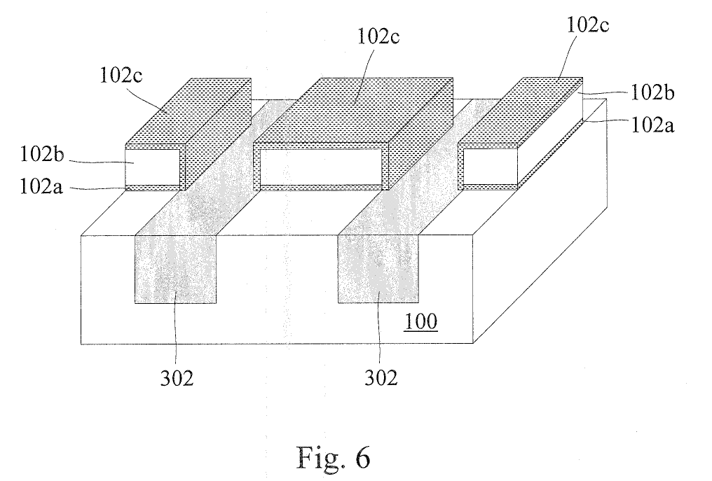

Please refer to FIG. 5. A tunnel oxide layer 102a is formed on the semiconductor substrate 100 through thermal oxidation process. Then, a plurality of floating gates 102b is deposited through low pressure chemical vapor deposition (LPCVD). Finally, a dielectric layer 102c is deposited on the floating gates 102b through thermal oxidation process to fabricate an oxide-nitride-oxide (ONO) structure, as shown in FIG. 6.

Referring to FIG. 6, through photoresist and etching processes, a plurality of separate ONO structures is formed to define the gate structures that are to be formed later.

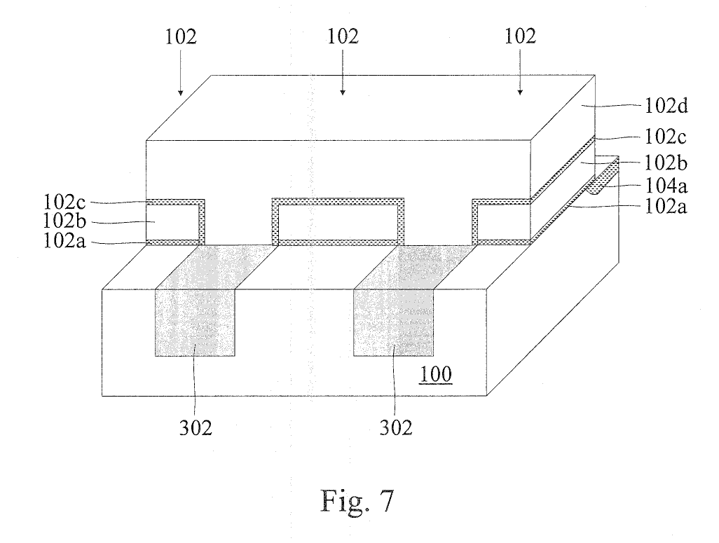

Please refer to FIG. 7. Through photoresist and etching processes, a control gate 102d is formed. As can be seen from FIG. 7, the control gate 102d is deposited over the separate ONO structures, so as to form a plurality of gate structures 102. The control gate 102d is in the form of a long and straight strip to connect the gate structures 102 to one another. The control gate 102d is arranged on the semiconductor substrate 100 in a direction normal to the STI structures 302. Each of the gate structures 102 includes a tunnel oxide layer 102a, a floating gate 102b, a dielectric layer 102c, and a control gate 102d. Then, use a mask (not shown) to cover a portion of the semiconductor substrate 100 that is located at one of two opposite lateral sides of the gate structures 102, and progress a shallow-doped drain ion implantation process to form a plurality of shallow-doped drain regions 104a in the portion of the semiconductor substrate 100 at that lateral side of the gate structures 102. Arsenic (As) ions are used in the shallow-doped drain ion implantation process at an implant dose of about 1×10¹⁴˜5×10¹⁵ atom/cm² and with an implant energy of about 10˜30 KeV.

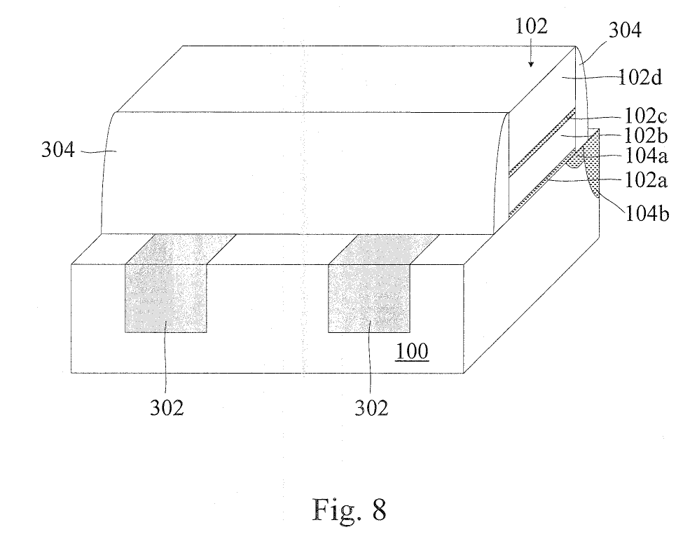

Please refer to FIG. 8. An oxide layer is deposited, and the deposited oxide layer is etched to form an oxide wall 304 at each of the two lateral sides of the gate structures 102 to serve as a buffer layer. In FIG. 8, the gate structures 102 are covered by the oxide walls 304 and therefore could not be completely shown. Then, use a mask (not shown) to cover the portion of the semiconductor substrate 100 at one lateral side of the gate structures 102, and progress a deep-doped drain ion implantation process to form a plurality of deep-doped drain regions 104b in the semiconductor substrate 100. The shallow-doped drain regions 104a and the deep-doped drain regions 104b are located in the portion of the semiconductor substrate 100 at the same lateral side of the gate structures 102 to form the drain regions 104 as shown in FIG. 1. Arsenic (As) ions are used in the deep-doped drain ion implantation process at an implant dose of about 1×10¹⁴˜5×10¹⁵ atom/cm² and with an implant energy of about 40˜60 KeV.

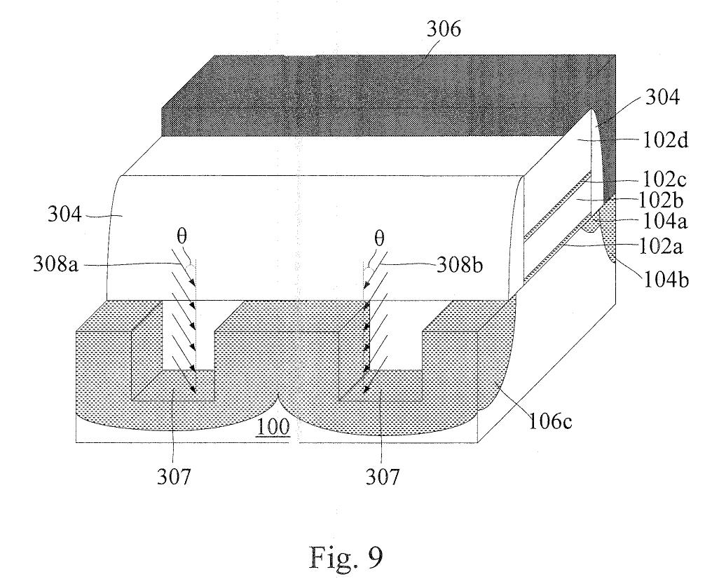

Please refer to FIG. 9. Use a mask 306 to cover the lateral side of the gate structures 102 having the shallow-doped drain regions 104a and the deep-doped drain regions 104b formed in the semiconductor substrate 100. Then, progress a self-align etch process to etch away portions of the STI structures 302 in the semiconductor substrate 100 at the other lateral side of the gate structures 102 without the drain regions 104, so that a plurality of openings 307 is formed thereat. Thereafter, a tilt ion implantation process is conducted. The tilt ion implantation process includes a first time tilt ion implantation process 308a and a second time tilt ion implantation process 308b, in both of which ions are implanted into the semiconductor substrate 100 at an incident angle θ of about 25 to 35 degrees, so that a continuous tilt-implanted source region 106c is formed in portions of the semiconductor substrate 100 located at the other lateral side of the gate structures 102 without the drain regions 104 and below the openings 307. In the first and the second time tilt ion implantation process 308a, 308b, N-type ions, such as arsenic (As) ions and phosphorus (P) ions, are implanted with an implant energy of about 20˜60 Key and at an implant dose of about 1×10¹⁴˜1×10¹⁵ atom/cm². The tilt-implanted source region 106c is corresponding to the source region 106 shown in FIG. 1.

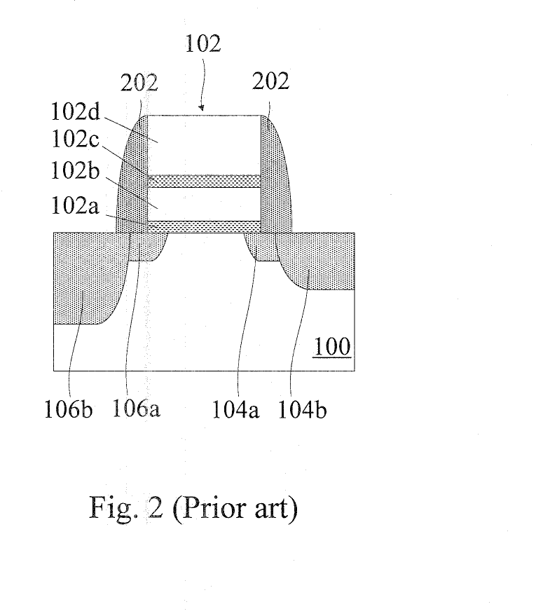

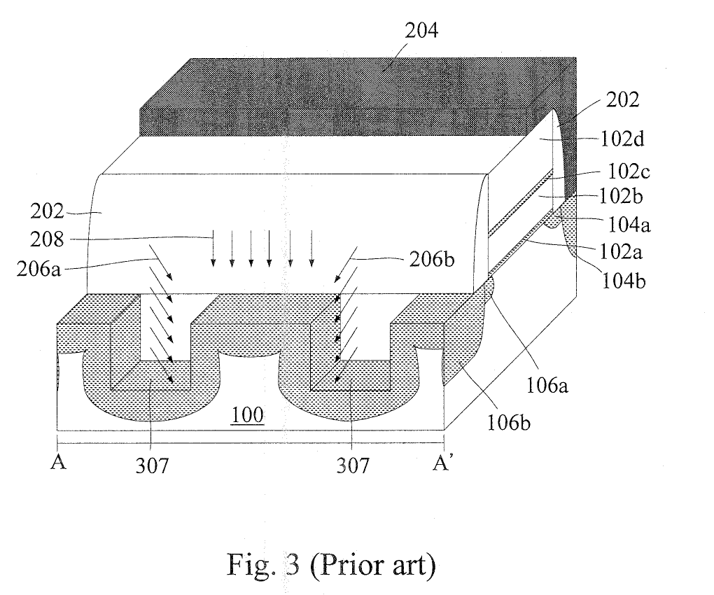

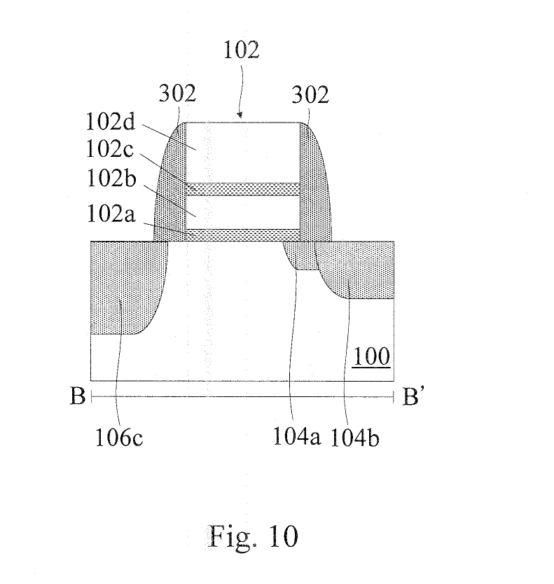

Please refer to FIG. 10, which is a cross sectional view of a NOR flash memory manufactured using the method of the present invention. The cross sectional view of FIG. 10 corresponds to a plane taken along the line B-B′ in FIG. 1. Compared to the conventional source ion implantation process that conducts three times of ion implantation as shown in FIGS. 2 & 3, the present invention is characterized in that it omits the second time source ion implantation process with a zero incident angle of implantation. Therefore, unlike the conventionally formed source region 106, the tilt-implanted source region 106c formed according to the method of the present invention does not include the first source region 106a that is relatively close to the shallow-doped drain region 104a. That is, compared to the conventional NOR flash memory manufactured using prior art, the NOR flash memory manufactured using the method of the present invention can have a larger distance between the source region 106c and the shallow-doped drain region 104a, and can therefore effectively reduce the probability of short channel effect (SCE).

In conclusion, in the method of manufacturing a NOR flash memory according to the present invention, two times of tilt ion implantation process are conducted to from the tilt-implanted source region and accordingly improve the distribution of the implanted source region, so that the probability of short channel effect would not become increased due to a too short distance between the drain region and the source region in the NOR flash memory.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A method of manufacturing a NOR flash memory, comprising the following steps:
forming a plurality of shallow trench isolation (STI) structures in a semiconductor substrate at intervals of about 50 to 150 nm;
forming a plurality of gate structures on the semiconductor substrate, and the gate structures being connected to one another via a control gate and formed into line; and the control gate being located on the semiconductor substrate in a direction normal to the STI structures;
progressing a shallow-doped drain ion implantation process to form a plurality of shallow-doped drain regions in portions of the semiconductor substrate at one of two opposite lateral sides of the gate structures;
forming an oxide wall at each of the two lateral sides of the gate structures;
progressing a deep-doped drain ion implantation process to form a plurality of deep-doped drain regions in portions the semiconductor substrate at one lateral side of the gate structures, so that the shallow-doped drain regions and the deep-doped drain regions are located in the semiconductor substrate at the same side of the gate structures;
progressing an etching process to etch away portions of the STI structures in the semiconductor substrate at the other lateral side of the gate structures without the drain regions, so as to form a plurality of openings; and
progressing a tilt ion implantation process to form a tilt-implanted source region in the semiconductor substrate at the other lateral side of the gate structures without the drain regions and below the openings.

2. The method of manufacturing a NOR flash memory as claimed in claim 1, wherein the semiconductor substrate is a p-type semiconductor substrate.

3. The method of manufacturing a NOR flash memory as claimed in claim 1, wherein the tilt ion implantation process includes a first time tilt ion implantation process and a second time tilt ion implantation process, and, in both of the first and the second time tilt ion implantation process, ions are implanted into the semiconductor substrate at an incident angle of about 25 to 35 degrees.

4. The method of manufacturing a NOR flash memory as claimed in claim 3, wherein, in the first and the second time tilt ion implantation process, n-type ions are implanted.

5. The method of manufacturing a NOR flash memory as claimed in claim 4, wherein, in the first and the second time tilt ion implantation process, ions are implanted with an implant energy of about 20˜60 KeV and at an implant dose of about 1×10¹⁴˜1×10¹⁵ atom/cm².
